(19) United States
(12) Patent Application Publication
(10) Pub. No.: US 2011/0220858 A1
(43) Pub. Date: Sep. 15, 2011

(54) SEMICONDUCTOR DEVICE AND METHOD OF MANUFACTURING THE SAME

(75) Inventors: Kyu-Man HWANG, Namdong-gu (KR); Junsoo Bae, Hwaseong-si (KR); Hwang-Ho Park, Bucheon-si (KR)

(73) Assignee: Samsung Electronics Co., Ltd., Suwon-si (KR)

(21) Appl. No.: 13/045,805

(22) Filed: Mar. 11, 2011

(30) Foreign Application Priority Data
Mar. 12, 2010 (KR) 10-2010-0022355

(51) Int. Cl. H01L 45/00

(52) U.S. Cl. 257/1; 438/382; 257/E45.002

(57) ABSTRACT

A semiconductor device and a method of manufacturing the same. The semiconductor device may include a lower electrode having a hollow cylindrical shape of which an upper portion is open, the lower electrode being disposed on a substrate, an insulating structure wrapping the lower electrode and including a nitride, a variable resistance pattern electrically connected to the lower electrode, and an upper electrode electrically connected to the variable resistance pattern.

### CROSS-REFERENCE TO RELATED APPLICATIONS

This U.S. non-provisional patent application claims priority under 35 U.S.C. §119 from Korean Patent Application No. 10-2010-0022355, filed on Mar. 12, 2010, the entire contents of which are hereby incorporated by reference.

### BACKGROUND

1. Field of the Invention

The present general inventive concept herein relates to semiconductor device and method of manufacturing the same, and more particularly, to a variable resistance memory device and a method of manufacturing the same.

2. Description of the Related Art

As a design rule of a variable resistance memory device becomes fine, a pollutant contaminant of a contact surface between a variable resistance layer and a lower electrode is becoming a big issue. During a cleaning process for removing a pollutant contaminant, a portion of oxide insulating layer wrapping a lower electrode is etched and thereby a void or a seam may be generated. A void or a seam may fatally affect a variable resistance memory device

### SUMMARY

Exemplary embodiments of the present general inventive concept provide a variable resistance memory device and a method of manufacturing the same. Exemplary embodiments of the present general inventive concept also provide insulating patterns formed to be adjacent to an upper portion of a lower electrode that includes a nitride to minimize the insulating patterns from being etched when a top surface of the lower electrode is cleaned during a manufacturing of a semiconductor device. Exemplary embodiments of the present general inventive concept may also minimize the generation of a void or a seam due to an etching of the insulating patterns so as to improve an electrical operation of the semiconductor device.

Additional features and utilities of the present general inventive concept will be set forth in part in the description which follows and, in part, will be obvious from the description, or may be learned by practice of the present general inventive concept.

Embodiments of the present general inventive concept provide a semiconductor device. The semiconductor device may include a lower electrode having a hollow cylindrical shape of which an upper portion is open, the lower electrode being disposed on a substrate, an insulator including a nitride to wrap the lower electrode, a variable resistance pattern electrically connected to the lower electrode, and an upper electrode electrically connected to the variable resistance pattern.

In exemplary embodiments of the present general inventive concept, the insulator can include a first insulating pattern to fill the hollow cylindrical shape of the lower electrode, and a second insulating pattern formed to be adjacent to an outer sidewall of the upper portion of the lower electrode.

In exemplary embodiments of the present general inventive concept, a vertical cross section of the lower electrode has a U character shape and a horizontal cross section of the lower electrode has a ring shape.

In exemplary embodiments of the present general inventive concept, the variable resistance pattern can he at least partly connected to the upper portion of the lower electrode.

In exemplary embodiments of the present general inventive concept, the semiconductor device includes a third insulating pattern to insulate a space between the variable resistance patterns, the third insulating pattern being formed on the lower electrode and the insulator, where the third insulating pattern includes an oxide.

In exemplary embodiments of the present general inventive concept, the insulator can include a fourth insulating pattern formed when removing one side of the lower electrode.

In exemplary embodiments of the present general inventive concept, a vertical cross section of the lower electrode can have a J character shape, an inversed J character shape, an L character shape or an inversed L character shape.

In exemplary embodiments of the present general inventive concept, the insulator can include a fifth insulating pattern extending when penetrating the second insulating pattern and a bottom surface of the lower electrode.

In exemplary embodiments of the present general inventive concept, a vertical cross section of the lower electrode has an L character shape or an inversed L character shape.

In exemplary embodiments of the present general inventive concept, the semiconductor device can include a sixth insulating pattern wrapping an outer sidewall of a lower portion of the lower electrode, the sixth insulating pattern being formed on a lower portion of the first insulating pattern, where the sixth insulating pattern includes an oxide.

In exemplary embodiments of the present general inventive concept, the semiconductor device can include a word line formed on the substrate, a selection unit electrically connected to the word line and the lower electrode, and a bit line electrically connected to the upper electrode.

Embodiments of the present general inventive concept may also provide a method of manufacturing a semiconductor device. The method may include forming a first insulating pattern having a first opening on a substrate, forming a lower electrode having a hollow cylindrical shape of which an upper portion is open in the first opening, forming a second insulating pattern including a nitride so as to fill the first opening where the lower electrode is formed, etching a portion of upper portion of the first insulating pattern, forming a third insulating pattern including a nitride on the etched first insulating pattern, and forming a variable resistance pattern and an upper electrode on the lower electrode.

In exemplary embodiments of the present general inventive concept, forming the second insulating pattern can include conformally forming a lower electrode layer on the first insulating pattern where the first opening is formed, forming a second insulating layer filling the first opening where the lower electrode layer is formed, and forming the second insulating pattern by etching the second insulating layer and the lower electrode layer so that a top surface of the first insulating pattern is exposed, where the second insulating pattern and the lower electrode are formed at the same time and the lower electrode has a vertical cross section of a U character shape and a horizontal cross section of a ring shape.

In exemplary embodiments of the present general inventive concept, top surfaces of the lower electrode, the first insulating pattern and the second insulating pattern can be formed on the same level with one another.

In exemplary embodiments of the present general inventive concept, forming the variable resistance pattern can include forming a fourth insulating pattern partly covering an upper portion of the lower electrode, forming a variable resistance layer filling a space between the fourth insulating patterns, and forming the variable resistance pattern by etching an upper portion of the variable resistance layer so that a top surface of the fourth insulating pattern is exposed.

In exemplary embodiments of the present general inventive concept, etching an upper portion of the variable resistance layer can be performed in a different chamber from a chamber in which the variable resistance layer is formed.

In exemplary embodiments of the present general inventive concept, the fourth insulating pattern can be formed using an oxide.

In exemplary embodiments of the present general inventive concept, the method can include forming a second opening by etching one side of the lower electrode, and forming a fifth insulating pattern including a nitride by filling the second opening, where a vertical cross section of the lower electrode has a J character shape, an inversed J character shape, an L character shape or an inversed L character shape.

In exemplary embodiments of the present general inventive concept, the method can include forming a second opening penetrating the second insulating pattern and a bottom surface of the lower electrode by etching the second insulating pattern and a bottom surface of the lower electrode, and forming a sixth insulating pattern including a nitride by filling the second opening, where a vertical cross section of the lower electrode has an L character shape or an inversed L character shape.

In exemplary embodiments of the present general inventive concept, the first insulating pattern can be formed using an oxide.

Exemplary embodiments of the present general inventive concept may also provide a semiconductor device, including a lower electrode having a base and two sidewalls extending from the base that are different lengths, the lower electrode disposed on a substrate, an insulator including a nitride, the insulator to fill the area between the two sidewalls of the lower electrode, to be disposed on at least one of the sidewalls, and to be disposed adjacent to outer portions of the two sidewalls, a variable resistance pattern electrically connected to the lower electrode, and an upper electrode electrically connected to the variable resistance pattern.

Exemplary embodiments of the present general inventive concept may also provide a semiconductor device including a lower electrode having a base and two sidewalls extending from the base that are different lengths, the lower electrode disposed on a substrate, an insulator including a nitride, the insulator having a first insulating pattern disposed adjacent to an outer side of each of the two sidewalls of the lower electrode, a second insulting pattern to fill an area between the two sidewalls of the lower electrode, a third insulating pattern formed on at least one of the two sidewalls of the lower electrode, a variable resistance pattern electrically connected to the lower electrode, and an upper electrode electrically connected to the variable resistance pattern.

Exemplary embodiments of the present general inventive concept may also provide a method of manufacturing a semiconductor device, the method including forming a lower electrode having a base and two sidewalls extending from the base that are different lengths on a substrate, forming an insulator including a nitride by filling the area between the two sidewalls of the lower electrode, disposing the insulator on at least one of the sidewalls, and disposing the insulator adjacent to outer portions of the two sidewalls, forming a variable resistance pattern that is electrically connected to the lower electrode, and forming an upper electrode that is electrically connected to the variable resistance pattern.

Exemplary embodiments of the present general inventive concept may also provide a semiconductor device, including a lower electrode having a first base with a first sidewall extending therefrom, and a second base with a second sidewall extending therefrom, where the first base and the second base of the lower electrode are spaced apart from one another and are disposed on a substrate, an insulator including a nitride, the insulator to fill the area between the first and second base and the first and second sidewalls, and to be disposed adjacent to outer portions of the first and second sidewalls, a variable resistance pattern electrically connected to the lower electrode, and an upper electrode electrically connected to the variable resistance pattern.

Exemplary embodiments of the present general inventive concept may also provide a method of manufacturing a semiconductor device, the method including forming a lower electrode having a first base with a first sidewall extending therefrom, and a second base with a second sidewall extending therefrom, where the first base and the second base of the lower electrode are spaced apart from one another and are disposed on a substrate, forming an insulator including a nitride, the insulator filling the area between the first and second base and the first and second sidewalls, and disposed adjacent to outer portions of the first and second sidewalls, forming a variable resistance pattern that is electrically connected to the lower electrode, and forming an upper electrode that is electrically connected to the variable resistance pattern.

Exemplary embodiments of the present general inventive concept may also provide a memory system having a memory including a lower electrode having a hollow cylindrical shape of which an upper portion is open, the lower electrode being disposed on a substrate, an insulator including a nitride to wrap the lower electrode, a variable resistance pattern electrically connected to the lower electrode, and an upper electrode electrically connected to the variable resistance pattern, and a controller to control data read and write operations to the memory.

### BRIEF DESCRIPTION OF THE DRAWINGS

The above and/or other utilities of the present general inventive concept will become apparent and more readily appreciated from the following description of the exemplary embodiments, taken in conjunction with the accompanying drawings, in which:

FIG. 1A is a circuit diagram illustrating a memory cell array of a semiconductor device in accordance with exemplary embodiments of the present general inventive concept;

FIG. 1B is a top plan view illustrating a memory cell array of a semiconductor device in accordance with exemplary embodiments of the present general inventive concept;

FIGS. 2A through 2R are cross-sectional views illustrating a method of manufacturing a semiconductor device in accordance with exemplary embodiments of the present general inventive concept;

FIGS. 3A through 3F are cross-sectional views illustrating a method of manufacturing a semiconductor device in accordance with exemplary embodiments of the present general inventive concept;

FIGS. 4A through 4E are cross-sectional views illustrating a method of manufacturing a semiconductor device in accordance with exemplary embodiments of the present general inventive concept;

FIG. 5A is a block diagram illustrating a memory card including a semiconductor device in accordance with exemplary embodiments of the present general inventive concept; and

FIG. 5B is a block diagram illustrating an information processing system that includes a memory system with a semiconductor memory in accordance with exemplary embodiments of the present general inventive concept is applied;

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present.

Embodiments of the present general inventive concept may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, exemplary embodiments of the present general inventive concept should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,'” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

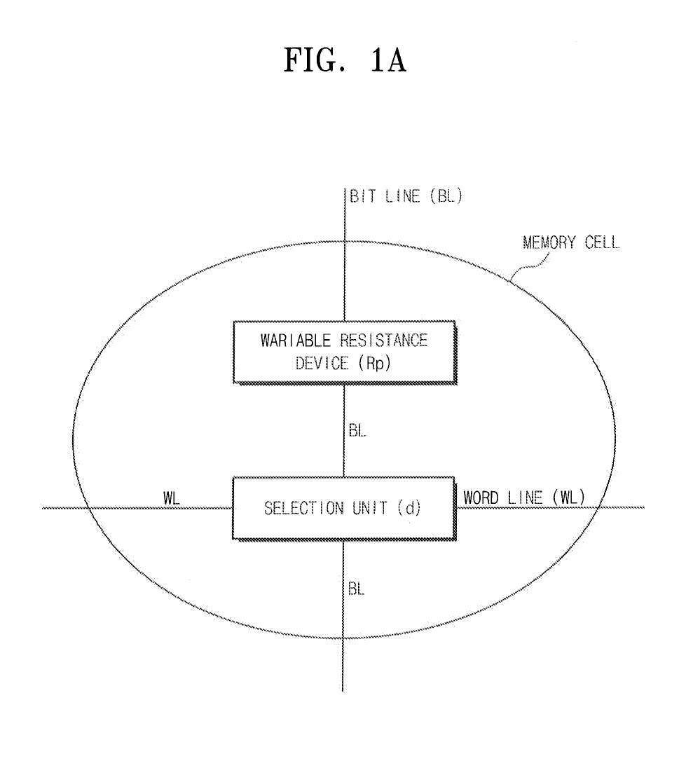

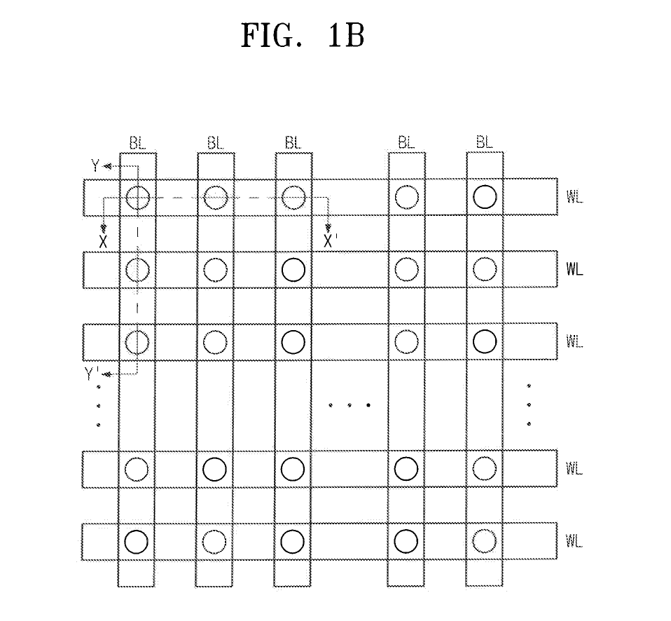

FIG. 1A is a circuit diagram illustrating a memory cell array of a semiconductor device in accordance with exemplary embodiments of the present general inventive concept. FIG. 1B is a top plan view illustrating a memory cell array of a semiconductor device in accordance with exemplary embodiments of the present general inventive concept.

Referring to FIGS. 1A and 1B, a plurality of memory cells may be arranged in a matrix shape. Each of memory cells may include a variable resistance device Rp and a selection unit D. The variable resistance device Rp may be connected between a bit line BL and the selection unit D. The selection unit D may be connected between the variable resistance device Rp and a word line WL. The variable resistance device Rp, for example, may include a phase change material, a ferroelectric material, or a magnetic material. A state of the variable resistance device Rp may be determined according to the amount of an electric current provided through the bit line BL.

The selection unit D may be connected between the variable resistance device Rp and the word line WL, and a supply amount of an electric current to the variable resistance device Rp may be controlled according to a voltage of the world line WL. The selection unit D may be a diode as described below in connection with the exemplary embodiments. The selection unit D may also be a metal oxide semiconductor (MOS) transistor or a bipolar transistor.

Hereinafter, in exemplary embodiments of the present general inventive concept, a variable resistance memory device including memory cells adopting a phase change material is described as a variable resistance device Rp by example. However, the present general inventive concept is not limited thereto, and may be applied to a resistance random access memory (RRAM), a ferroelectric RAM (FRAM) and a magnetic RAM (RRAM).

In exemplary embodiments of the present general inventive concept, a resistance of a phase change material, which is the variable resistance device Rp, may be changed according to a temperature. That is, a phase change material may have an amorphous state having a predetermined first resistance (e.g., a relatively high resistance) and a crystal state having a predetermined second resistance (e.g., a relatively low resistance) according to a temperature and a cooling time. The variable resistance device Rp can generate heat (e.g., a Joule's heat) according to the amount of an electric current provided through a lower electrode, thereby heating a phase change material. The heat (e.g., Joule's heat) may be generated according to (e.g., in proportion to) resistivity of a phase change material and a supply time of an electric current.

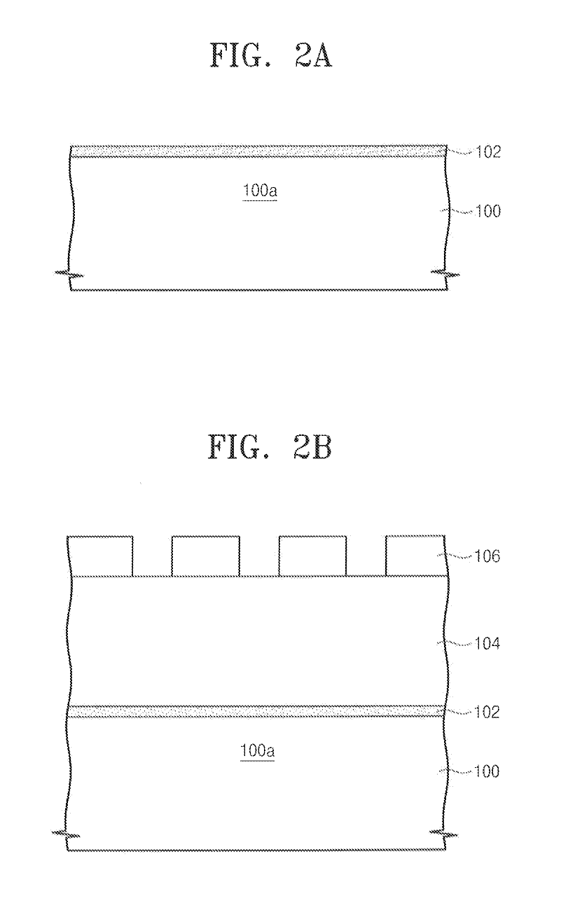

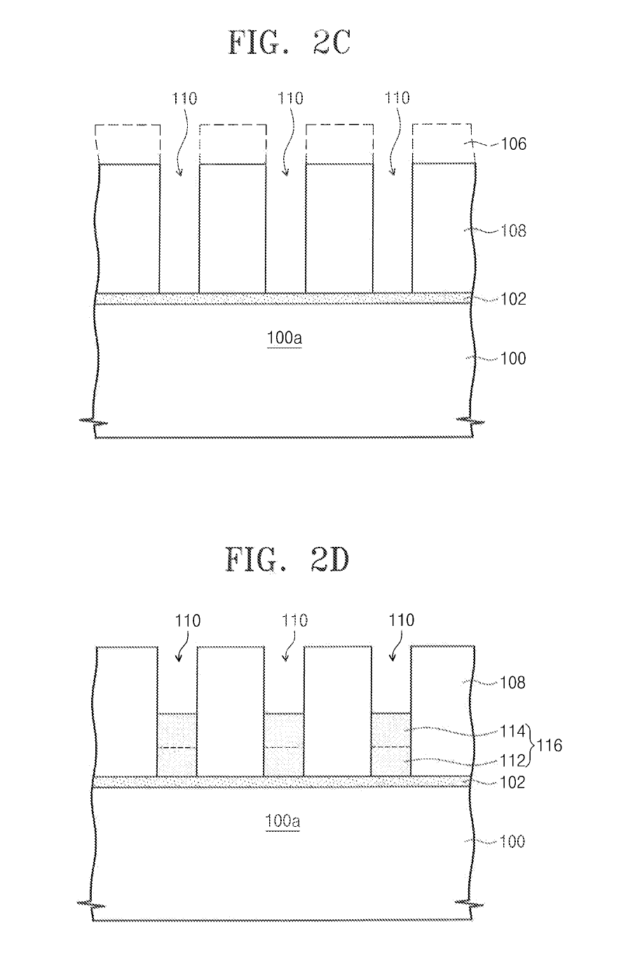

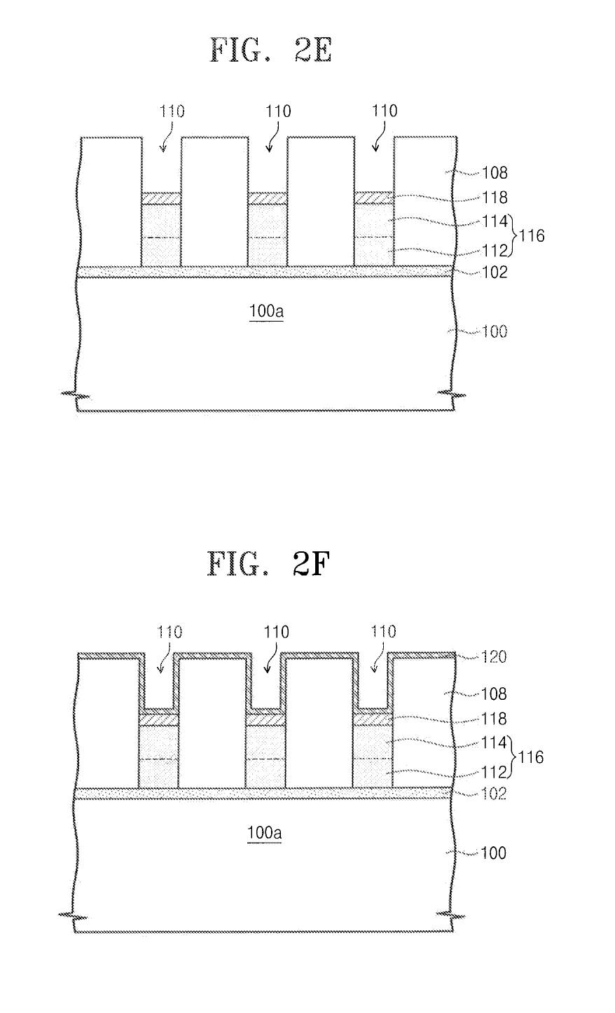

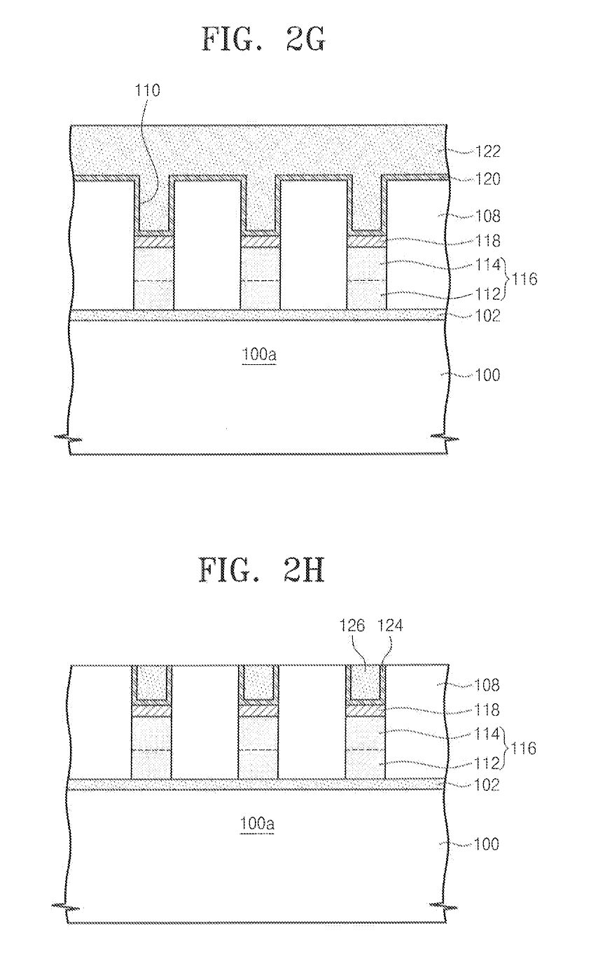

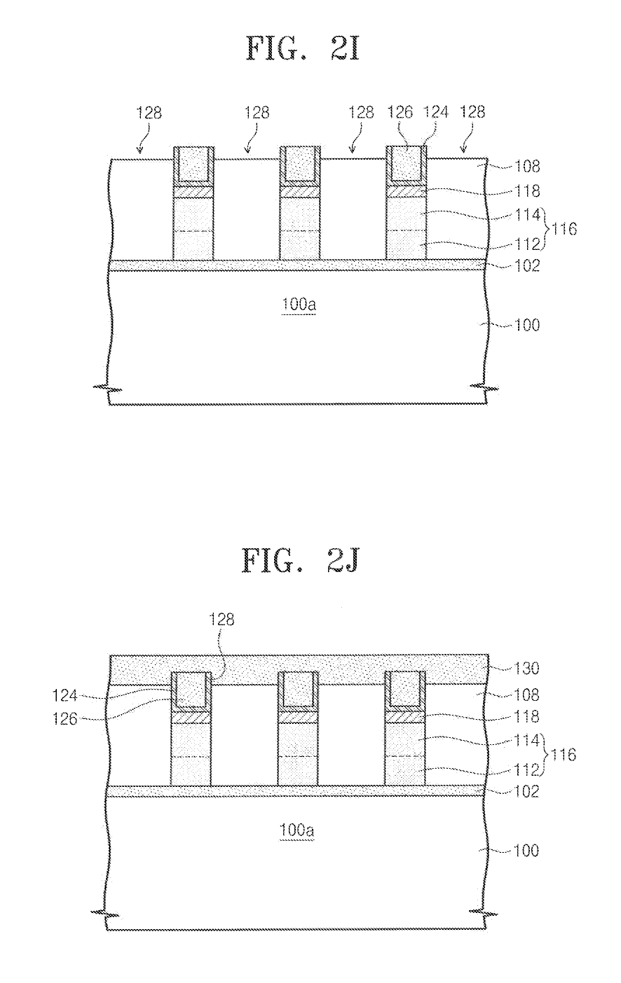

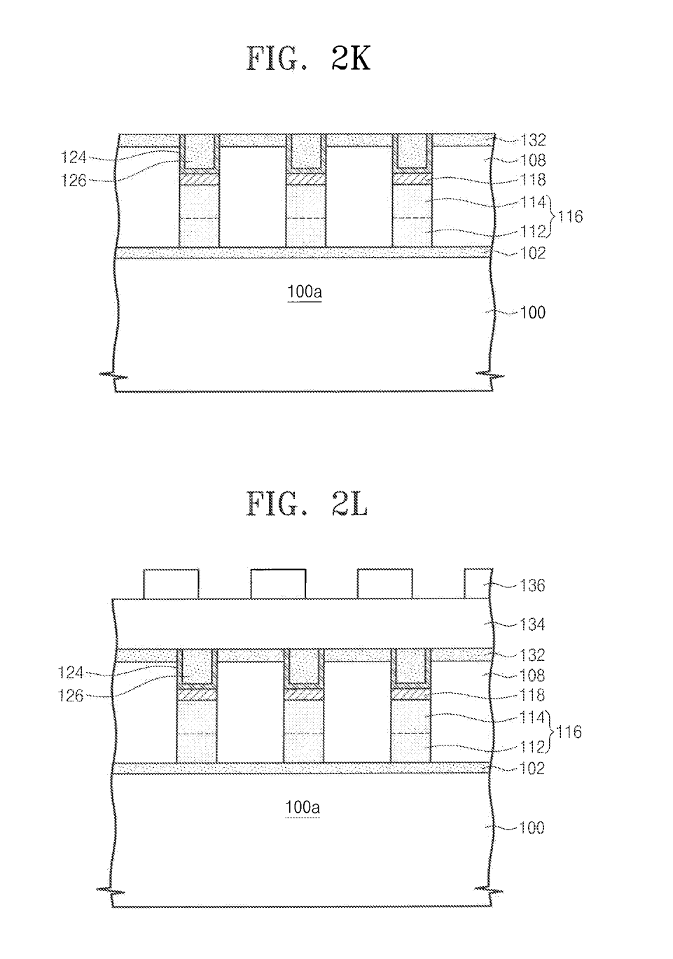

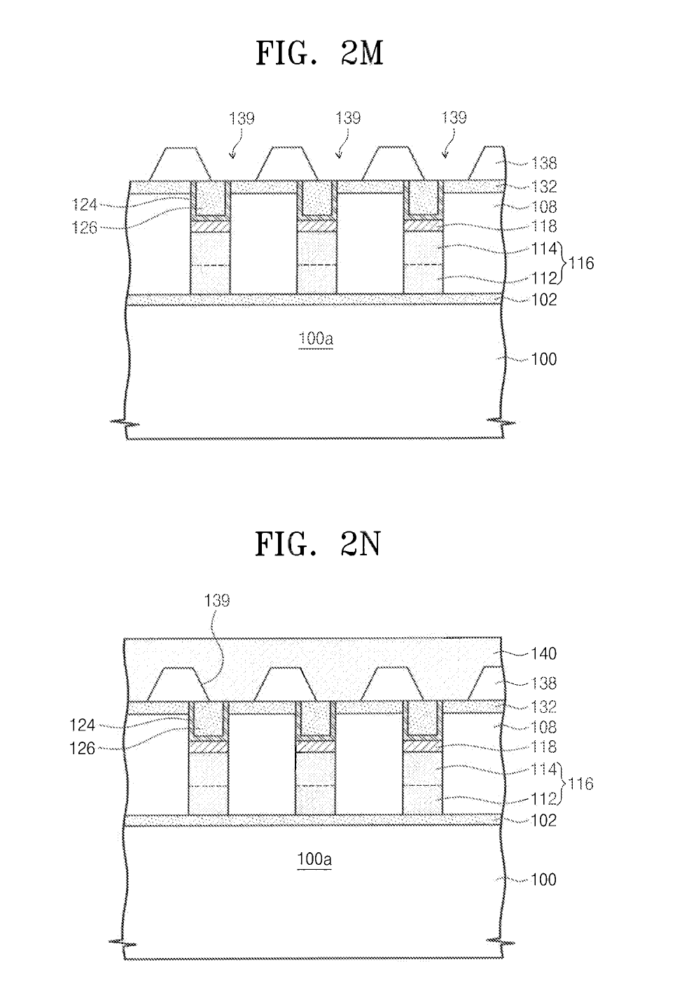

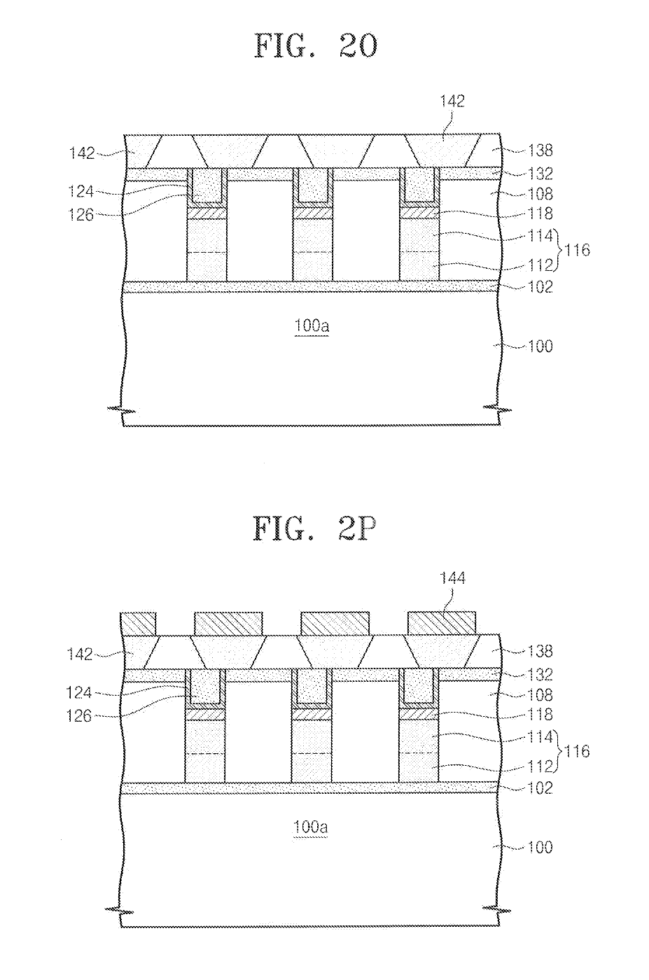

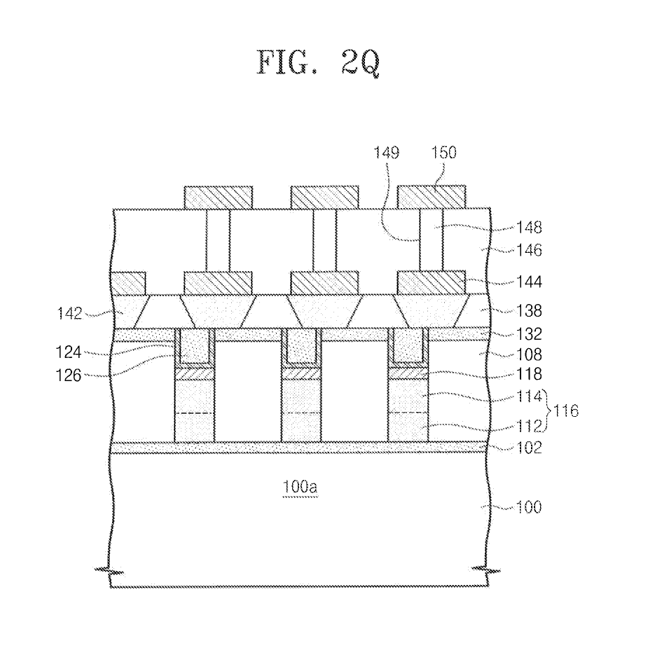

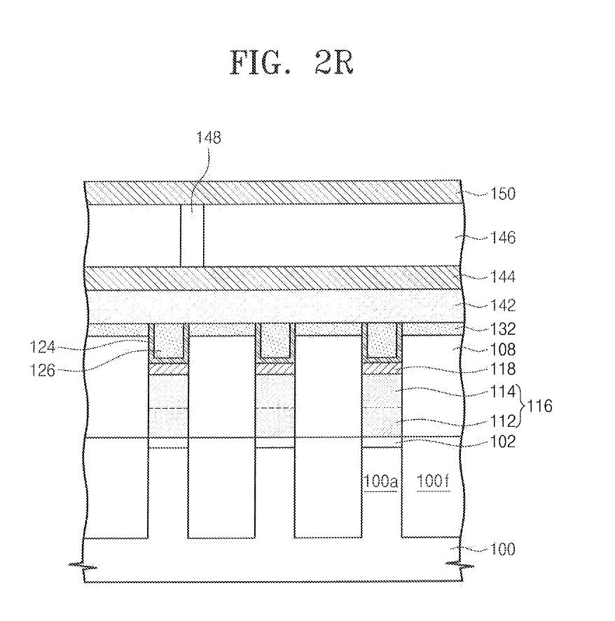

FIGS. 2A through 2R are cross-sectional views illustrating a method of manufacturing a semiconductor device in accordance with exemplary embodiments of the present general inventive concept. More specifically, FIGS. 2A through 2R are cross-sectional views taken along the line X-X′ of a semiconductor device illustrated in FIG. 1B.

Referring to FIG. 2A, a word line 102 may be formed on a substrate 100. The substrate 100 may include a semiconductor substrate such as a silicon Si substrate, a germanium Ge substrate, a silicon-germanium Si—Ge substrate, a silicon-on-insulator (SOI) substrate, a germanium-on-insulator (GOI) substrate, or the like. Also, the substrate 100 may be a substrate doped with an impurity. For example, the substrate 100 may be a P-type substrate doped with a P-type impurity. The P-type impurity may include at least one of boron B, gallium Ga, and indium In.

A field insulating pattern 100f (referring to FIG. 2R) may be formed in the substrate 100 using a shallow trench isolation (STI) process and/or any other suitable operation to form a field insulation pattern in a substrate according to the exemplary embodiments of the present general inventive concept disclosed herein. The field insulating pattern 100f may be a field region in the substrate 100, and an active region 100a extending in a first direction may be defined by the field region 100f.

According to exemplary embodiments of the present general inventive concept, the word line 102 may be formed by implanting a second impurity into the active region 100a of the substrate 100. For example, when the substrate 100 is a P-type silicon substrate, the second impurity may be an N-type impurity. The N-type impurity may include at least one of phosphorous P, arsenic As, and antimony Sb.

According to exemplary embodiments of the present general inventive concept, when an epitaxial semiconductor layer is formed on the substrate 100, the word line 102 may be formed by implanting the second impurity into the epitaxial semiconductor layer. According to exemplary embodiments of the present general inventive concept, the word line 102 may be formed using metal or at least one metal compound.

The word line 102 formed on the substrate 100 may extend in the first direction, which is the same direction as an extension direction of the active region 100a, For example, the word line 102 may be the plural number of word lines such that a plurality of word lines 102 may be formed in parallel to be spaced at predetermined intervals (e.g., a same interval) apart from one another.

Referring to FIG. 2B, a first insulating layer 104 and a first mask 106 may be formed on the substrate 100 including the word line 102.

According to exemplary embodiments of the present general inventive concept, the first insulating layer 104 may include an oxide (for example, a silicon oxide). A silicon oxide may include, for example, borosilicate glass (BSG), phosphosilicate glass (PSG), borophosphosilicate glass (BPSG), plasma enhanced tetra ethyl ortho silicate (PE-TEOS), or high density plasma (HDP).

The first insulating layer 104 may be formed by performing a chemical vapor deposition (CVD) process, a low pressure CVD (LPCVD), or a plasma enhanced CVD (PECVD) process.

The first mask 106 may be formed on the first insulating layer 104. The first mask 106 may include photoresistor or a nitride. For example, a silicon nitride may be used as a nitride in the first mask 106.

Referring to FIG. 2C, the first insulating layer 104 may be etched to form first insulating patterns 108.

More specifically, the first insulating layer 104 may be etched by an etching process using the first mask 106 as an etch mask. The etching process may be an anisotropic etching process and/or any other suitable etching process so as to etch the first insulating layer 104 according to the exemplary embodiments of the present general inventive concept as disclosed herein. The anisotropic etching process may include a plasma etching process or a reactive ion etching (RIF) process.

When the first insulating process 104 is etched using the first mask 106, the first insulating patterns 108 may be formed on the substrate 100, and first openings 110 to expose the word line 102 may be formed between the first insulating patterns 108.

When the first insulating patterns 108 are formed, the first mask 106 may be removed. When the first mask 106 includes photoresist, the first mask 106 may be removed by an ashing process and a strip process, and/or any other suitable process to remove the first mask 106.

Referring to FIG. 2D, a selection unit 116 electrically connected to the word line 102 exposed by the first opening 110 may be formed.

According to exemplary embodiments of the present general inventive concept, the selection unit 116 may be a diode. The selection unit 116 may include a lower silicon layer 112 and an upper silicon layer 114. The lower silicon layer 112 may be doped with a third impurity and the upper silicon layer 114 doped with a fourth impurity. For example, the lower silicon layer 112 may be doped with a P-type impurity, and the upper silicon layer 114 may be doped with an N-type impurity.

More specifically describing a process of forming the selection unit 116, the lower silicon layer 112 doped with the third impurity may be formed by a first selective epitaxial growth (SEG) process using the word line exposed by the first opening 110 as a seed. A doping of the third impurity may be performed by an ion implantation or an in-situ process. The upper silicon layer 114 doped with the fourth impurity may be formed by a second selective epitaxial growth (SEG) process using the lower silicon layer 112 as a seed. A doping of the fourth impurity may be performed by an ion implantation or an in-situ process.

For example, when the substrate 100 is a P-type silicon substrate and the word line 102 includes an N-type impurity, the lower silicon layer 112 of the selective device 116 may include a P-type impurity and the upper silicon layer 114 of the selective device 116 may include an N-type impurity.

The selective device 116 may be formed inside a lower portion of the first opening 110 and may be formed so as not to fully fill the first opening 110. That is, the selective device 116 may be formed in at least a portion of the first opening 110. An upper portion of the first opening 110 may be in an open state.

Referring to FIG. 2E, an ohmic pattern 118 may be formed on the selective device 116.

According to exemplary embodiments of the present general inventive concept, a metal layer (not illustrated) may be formed on the selection unit 116. A silicidation process may be performed on the metal layer and the upper silicon layer 114 of the selection unit 116 to form the ohmic pattern 118. The silicidation process may include the following operations. A first thermal process may be performed on the metal layer and the selection unit 116. Metal and silicon included in the metal layer and the upper silicon layer 114 respectively may be changed into metal silicide by the first thermal process. Unreacted silicon and unreacted metal may be removed through a cleaning process. The ohmic pattern 118 including metal silicide having a chemically stable structure may be formed through a second thermal process.

The ohmic pattern 118 may include titanium silicide TiSi, cobalt silicide CoSi, tantalum silicide TaSi, tungsten silicide WSi, and/or any suitable combinations thereof to carry out the exemplary embodiments of the present general inventive concept disclosed herein.

The ohmic pattern 118 may be formed so as not to fully fill the first opening 110. That is, the ohmic pattern 118 may be formed in at least a portion of the first opening 110. When the ohmic pattern 118 is formed, an upper portion of the first opening 110 may be in an open state.

Referring to FIG. 2F, a lower electrode layer 120 may be conformally formed on the ohmic pattern 118 and the first insulating patterns 108.

The lower electrode layer 120 may be formed (e.g., continuously formed) along a surface profile of the ohmic pattern 118 and the first insulating patterns 108. The lower electrode layer 120 may be formed so as not to fully fill the first opening 110. That is, the lower electrode layer may be formed so as to fill at least a portion of the first opening 110.

The lower electrode layer 120 may include metal or metal compound. For example, the lower electrode layer 120 may be formed using tungsten W, titanium Ti, tantalum Ta, aluminum Al, molybdenum Mo, niobium Nb, zirconium Zr, tungsten nitride WN, titanium nitride TiN, tantalum nitride TaN, aluminum nitride AIN, molybdenum nitride MoN, niobium nitride NbN, zirconium nitride ZrN, titanium aluminum nitride TiAlN, tantalum aluminum nitride TaAlN, zirconium aluminum nitride ZrAlN, and/or any suitable combinations or compounds thereof to carry out the exemplary embodiments of the present general inventive concept disclosed herein. Using at least the materials listed above, the lower electrode 120 may be formed to have a single layer structure or a multi-layer structure.

Referring to FIG. 2G, a second insulating layer 122 may be formed on the lower electrode layer 120.

The second insulating layer 122 may be formed on the lower electrode layer 120 when fully filling the first opening 110. The second insulating layer 122 may include nitride (for example, silicon nitride). The second insulating layer 122 may be formed using a chemical vapor deposition (CVD) process or an atomic layer deposition (ALD) process,

Referring to FIG. 2H, the second insulating layer 122 and the lower electrode layer 120 may be etched to form a second insulating pattern 126 and a lower electrode 124.

More specifically, an upper portion of the second insulating layer 122 may be first-etched so that an upper portion of the lower electrode layer 120 is exposed. The lower electrode layer 120 and the second insulating layer 122 may be second-etched so that an upper portion of the first insulating patterns 108 is exposed. The first and second etching may be performed using an etch-back process or a chemical mechanical polishing (CMP) process. The lower electrode 124 and the second insulating pattern 126 may be formed on the ohmic pattern 118 using the above-described etching process.

The lower electrode 124 may have a hollow cylindrical shape of which an upper portion is open and a cross section of the lower electrode 124 may have a U character shape. The second insulating pattern 126 may formed in the hollowness of the lower electrode 124 and may have a cylindrical shape.

Referring to FIG. 2I, a portion of upper portion of the first insulating patterns 108 may be etched.

Upper portions of the first insulating patterns 108 may be etched to form a second opening 128 defined by the lower electrode 124. The first insulating patterns 108 may be exposed to a bottom surface of the second opening 128.

In exemplary embodiments of the present general inventive concept, when the first insulating patterns 108 includes an oxide, the second insulating pattern 126 can include a nitride, the lower electrode 124 can include a metal or metal compound, and the upper portions of the first insulating patterns 108 may be etched using a wet etching. An etching solution used in a wet etching may have a characteristic that an etching rate with respect to an oxide is substantially greater than an etching velocity with respect to a nitride, metal, or metal compound. Thus, the second insulating pattern 126 and the lower electrode 124 may substantially not be etched when the upper portions of the first insulating patterns 108 are etched.

According to exemplary embodiments of the present general inventive concept, when a protection pattern covering the first insulating patterns 108 and the lower electrode 124 is formed, the second insulating pattern 126 may be etched. The etching may be performed by an anisotropic etching process or a wet etching process.

Referring to FIG. 2J, a third insulating layer 130 may be formed on the lower electrode 124, the first insulating patterns 108, and the second insulating patterns 126.

The third insulating layer 130 may be formed on the lower electrode 124, the first insulating patterns 108, and the second insulating patterns 126 so as to fill the second opening 128. The third insulating layer 130 may include a nitride (for example, a silicon nitride).

Referring to FIG. 2K, the third insulating layer 130 may be etched to form a third insulating pattern 132.

More specifically, the third insulating pattern 132 may be formed by etching the third insulating layer 130 so that upper portions of the second insulating pattern 126 and the lower electrode 124. The etching may be performed by an etch-back process, a chemical mechanical polishing (CMP) process, or any other suitable process to form the third insulating pattern 132 according to the exemplary embodiments of the present general inventive concept as disclosed herein.

Although not illustrated in the drawings, when the third insulating pattern 132 is formed, the lower electrode 124 may be cleaned, At least a part of the lower electrode 124 which is in contact with a variable resistance pattern (142, referring to FIG. 2O) may be a part that may change a phase of the variable resistance pattern 142 and may be called a program volume. A cleaning process may be performed on the program volume to remove a substance (e.g., a foreign substance) such as a natural oxide. The cleaning process may use a cleaning solution removing a natural oxide, or may use plasma.

When the second and third insulating patterns 126 and 132 include an oxide, at least a portion of the second and third insulating patterns 126 and 132 may be etched during the cleaning process. According to exemplary embodiments of the present general inventive concept, as the second and third insulating patterns 126 and 132 can include a nitride, the second and third insulating patterns 126 and 132 may substantially not be etched while the lower electrode 124 is cleaned. Thus, it may be suppressed that a void or a seam is generated on a recessed portion formed by etching a portion of upper portion of the second and third insulating patterns 126 and 132. That is, formation of a void or a seam may be minimized by etching an upper portion of the second and/or third insulating patterns 126 and 132 that include a nitride.

When a void or a seam is generated in the second and third insulating patterns 126 and 132, the variable resistance pattern 142 may be formed in the void and the seam. The variable resistance pattern 142 formed in the void or the seam may have an increased area which is in contact with the lower electrode 124. In this case, an electric current applied to the lower electrode 124 may increase so as to reset the variable resistance pattern 142. A distribution of an applied reset electric current may be non-uniform according to a magnitude and a shape of the void or the seam. Thus, a characteristic of a reset electric current may be improved by suppressing a generation of a void or a seam from the second and third insulating patterns 126 and 132. That is, characteristics of the electric current in the semiconductor device can be increased and/or improved by minimizing the generation of a void or a seam in the second and third insulating patterns 126 and 132.

Referring to FIG. 2L, a fourth insulating layer 134 and a second mask 136 may be formed on the lower electrode 124 and the second and third insulating patterns 126 and 132.

The fourth insulating layer 134 may include an oxide, a nitride, or an oxynitride (for example, silicon oxide, silicon nitride or silicon oxynitride),

The second mask 136 may be formed on the fourth insulating layer 134. The second mask 136 may include a nitride or a photoresist. The second mask 136 may have a line shape extending in a second direction.

Referring to FIG. 2M, the fourth insulating layer 134 may be etched to form a fourth insulating pattern 138.

More specifically, the fourth insulating layer 134 may be etched by an etching process using the second mask 136 to form the fourth insulating pattern 138. The etching may be performed using an anisotropic etching process, for example, a plasma etching or an active ion etching process. Because of a characteristic of an anisotropic etching, the fourth insulating pattern 138 may have a width which may increase in a direction to a lower portion. That is, a base portion of the fourth insulating pattern 138 that is adjacent and/or in contact with the third insulating pattern may be wider than a top portion of the fourth insulating pattern which is opposite the base portion. Thus, the fourth insulating pattern 138 may have a sloping sidewall.

When etched, the fourth insulating pattern 138 may have a line shape extending in the second direction. The fourth insulating pattern 138 may be formed to cover at least a portion of upper portion of the lower electrode 124 so as to reduce an area that the lower electrode 124 is in contact with a variable resistance pattern that may be subsequently formed.

The etching process may form a third opening 139 defined by the fourth insulating pattern 138. The third opening 139 may have a line structure extending in the same second direction as the fourth insulating pattern 138.

Referring to FIG. 2N, a variable resistance layer 140 may be formed on the fourth insulating pattern 138.

The variable resistance layer 140 may be formed on the fourth insulating pattern 138 when filling the third opening 139.

The variable resistance layer 140 may include a phase change material such as chalcogenide material. The variable resistance layer 140 may be, for example, SeSbTe, GeSbTe, GeTeAs, SnTeSn, GeTe, SbTe, SeTeSn, GeTeSe, SbSeBi, GeBiTe, InSe, GaTeSe or InSbTe. According to exemplary embodiments of the present general inventive concept, the variable resistance layer 140 may include a phase change material doped with carbon C, nitrogen N, silicon Si, or oxygen O.

Referring to FIG. 2O, an upper portion of the variable resistance layer 140 may be etched to form a variable resistance pattern 142.

More specifically, an upper portion of the variable resistance layer 140 may be etched so that a top surface of the fourth insulating pattern 138 is exposed to form a variable resistance pattern 142 defined by the fourth insulating pattern 138. The etching may be performed by a chemical mechanical polishing (CMP) process. The variable resistance pattern 142 may extend in the second direction (e.g., the same direction that the second mask 136 that has a line shape may extend in as described above in connection with FIG. 2L).

The process of forming the variable resistance layer 140 of FIG. 2N and the chemical mechanical polishing (CMP) process of FIG. 2O may be performed in ex-situ. The process of forming the variable resistance layer 140 may be performed in a deposition process chamber, and the chemical mechanical polishing (CMP) process may be performed on the variable resistance layer 140 in another chamber. That is, the variable resistance layer 140 may be formed in a first chamber, and a CMP process can be performed on the variable resistance layer 140 in a second chamber.

When the substrate 100 including the variable resistance layer 140 moves between chambers, an oxide may contain moisture that is greater than a predetermined amount of moisture (e.g., excessive moisture), or structures formed on the substrate 100 may be contaminated by a foreign substance. The fourth insulating pattern 138 including an oxide may contain an amount of moisture that is greater than a predetermined amount (e.g., excessive moisture). When the second and third insulating patterns 126 and 132 include an oxide, the second and third insulating patterns 126 and 132 containing an amount of moisture that is greater than a predetermined amount (e.g., excessive moisture) may become a more serious problem than the case of the fourth insulating pattern 138. That is, amounts of moisture in the second and third insulating patterns 126 and 132 that are greater than a predetermined amount may increase the number of incorrect operations of a semiconductor device.

Since the lower electrode 124 which is in contact with the variable resistance pattern 142 may change a phase of material of the variable resistance pattern 142, moisture contained in the second and third insulating patterns 126 and 132 adjacent to the lower electrode 124 and the variable resistance pattern 142 may be a cause of an incorrect operation of a semiconductor device. Thus, in the exemplary embodiments of the present general inventive concept, since the second and third insulating patterns 126 and 132 which are in contact with an upper sidewall of the lower electrode 124 are formed of a nitride and a nitride contains less moisture than an oxide, an incorrect electrical operation of a semiconductor device may be minimized and/or prevented.

Referring to FIG. 2P, an upper electrode 144 that is electrically connected to the variable resistance pattern 142 may be formed.

More specifically, an upper electrode layer (not illustrated) may be formed on the variable resistance pattern 142 and the fourth insulating pattern 138, The upper electrode layer may include metal or metal compound, The upper electrode layer may include, for example, tungsten W, titanium Ti, tantalum Ta, aluminum Al, molybdenum Mo, niobium Nb, zirconium Zr, nickel Ni, ruthenium Ru, palladium Pd, hafnium Hf, iridium Ir, platinum Pt, tungsten nitride WN, titanium nitride TiN, tantalum nitride TaN, aluminum nitride AlN, molybdenum nitride MoN, niobium nitride NbN, zirconium nitride ZrN, ruthenium nitride RuN, hafnium nitride HfN, iridium nitride IrN, platinum nitride PtN, titanium aluminum nitride TiAlN, tantalum aluminum nitride TaAlN, zirconium aluminum nitride ZrAlN, and/or any suitable compounds thereof to form an upper electrode according to exemplary embodiments of the present general inventive concept disclosed herein.

The upper electrode layer may be patterned to form the upper electrode 144 electrically connected to the variable resistance pattern 142.

Referring to FIGS. 2Q and 2R, a bit line 150 electrically connected to the upper electrode 144 may be formed.

According to exemplary embodiments of the present general inventive concept, when a fifth insulating layer 146 is formed on the upper electrode 144, a contact hole 149 may be formed in the fifth insulating layer 146. An upper surface of the upper electrode 144 may be exposed to a bottom surface of the contact hole 149. A conductive layer may be formed on the fifth insulating layer 146 when filling the contact hole 149. A third mask (not illustrated) may be formed on the conductive layer. The conductive layer may be etched using the third mask as an etching mask to form the bit line 150 and a contact 148. The bit line 150 may extend in the second direction and the contact 148 may electrically connect the bit line 150 and the upper electrode 144.

According to exemplary embodiments of the present general inventive concept, the bit line 150 that is directly connected to the upper electrode 144 without the contact 148 may be formed. The bit line 150 may extend in the second direction.

A structure of a semiconductor device in accordance with the exemplary embodiments of the present general inventive concept is not limited to be manufactured by the manufacturing method illustrated in FIGS. 2A-2R and described above. A structure of a semiconductor device in accordance with the exemplary embodiments of the present general inventive concept may be realized by various manufacturing methods.

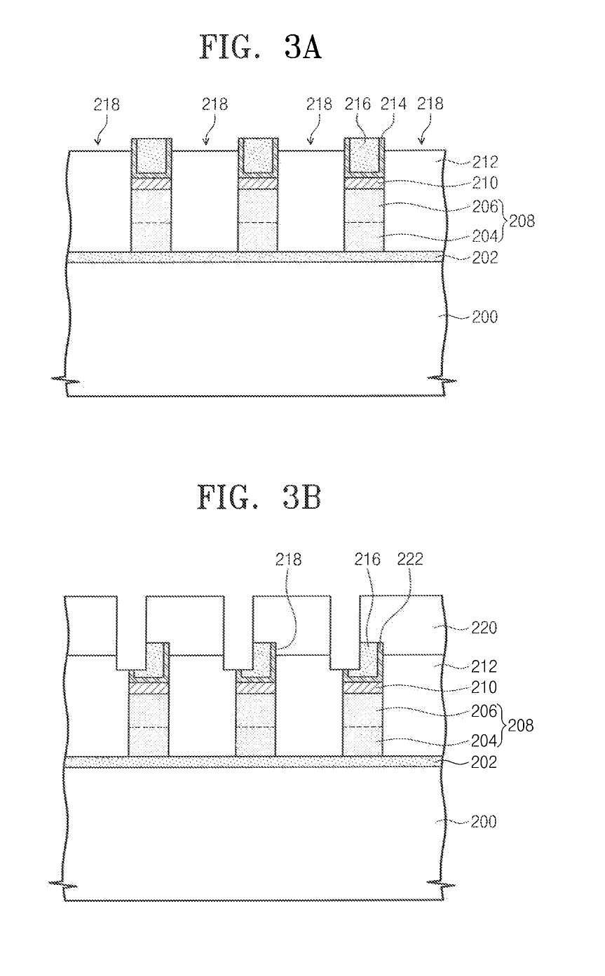

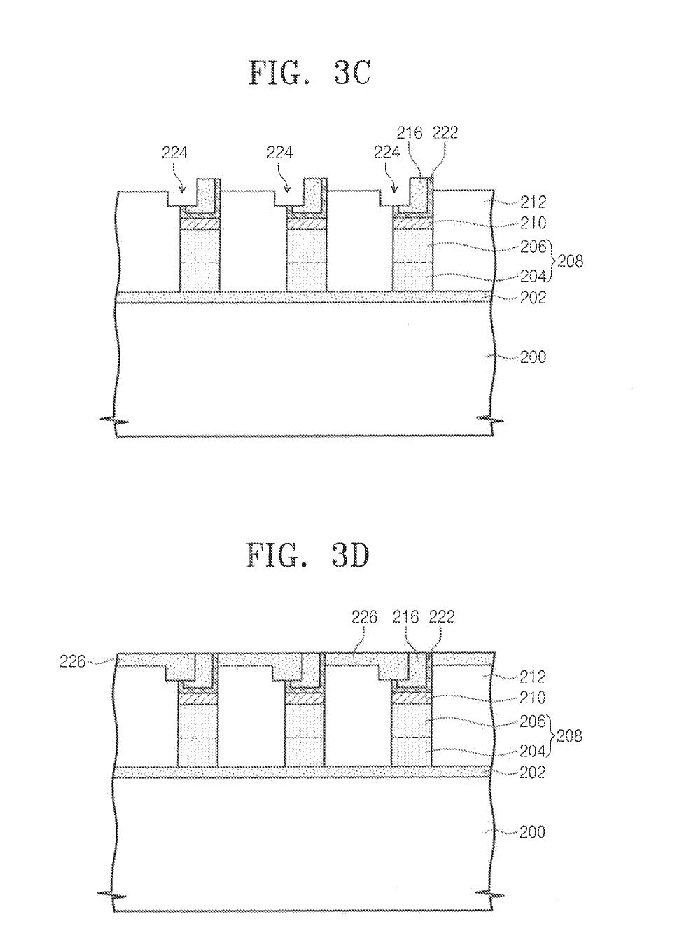

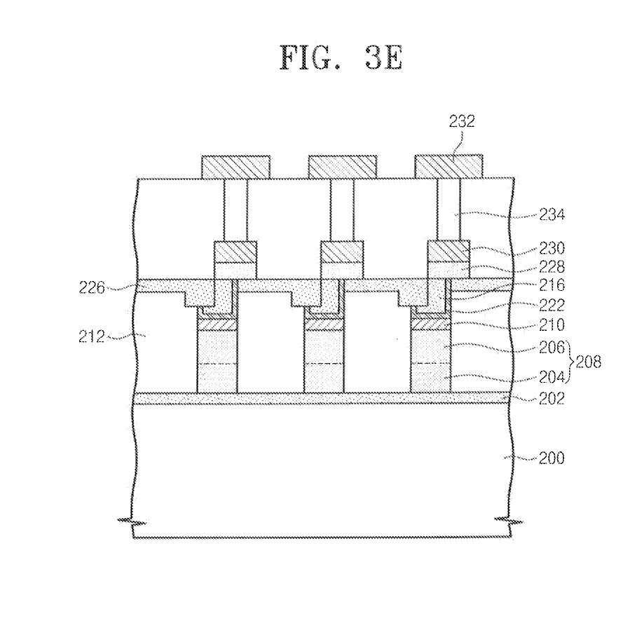

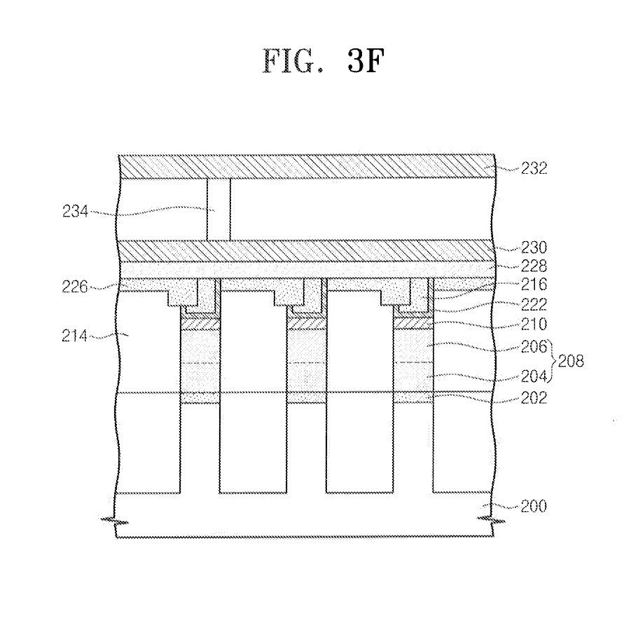

FIGS. 3A through 3F are cross-sectional views illustrating a method of manufacturing a semiconductor device in accordance with exemplary embodiments of the present general inventive concept. FIGS. 3A through 3E are cross-sectional views taken along the line X-X′ of a semiconductor device illustrated in FIG. 1B. FIG. 3F is a cross-sectional view taken along the line Y-Y′ of a semiconductor device illustrated in FIG. 1B.

Referring to FIG. 3A, a word line 202, a selection unit 208, an ohmic pattern 210, a preliminary lower electrode 214, and first and second insulating patterns 212 and 216 may be formed on a substrate 200. The selection unit 208 may be a diode, a bipolar junction transistor, or a MOS transistor. The selection unit 208 may include a lower silicon layer 204 and an upper silicon layer 206. The lower silicon layer 204 may be doped with an impurity and the upper silicon layer 206 may be doped with another impurity. For example, the lower silicon layer 204 may be doped with a P-type impurity, and the upper silicon layer 206 may be doped with an N-type impurity.

The preliminary lower electrode 214 may have a hollow cylindrical shape of which an upper portion is open. A vertical cross section of the preliminary lower electrode 214 may have a U character shape.

The second insulating pattern 216 may be formed by filling a hollowness of the preliminary lower electrode 214. A top surface of the second insulating pattern 216 may be even with a top surface of the preliminary lower electrode 214.

A top surface of the first insulating pattern 212 may be substantially lower than a top surface of the second insulating pattern 216, A first opening 218 may be formed on an upper portion of the second insulating pattern 216.

Since a process of forming the word line 202, the selection unit 208, the ohmic pattern 210, the preliminary lower electrode 214, and the first and second insulating patterns 212 and 216 is similar to the process illustrated in FIGS. 2A through 2I and as described above, a detailed description will be omitted.

Referring to FIG. 3B, one side of the preliminary lower electrode 214 may be etched to form a lower electrode 222.

More specifically, a first mask 220 exposing one side of the preliminary lower electrode 214 may be formed. The first mask 220 may expose one side of the preliminary lower electrode 214 and portions of the first and second insulating patterns 212 and 216. One side of the preliminary lower electrode 214 may be etched using the first mask 220 as an etching mask.

The lower electrode 222 may have a vertical cross section of a J character shape, an inversed J character shape, an L character shape or an inversed L character shape from the etching process according to an etched depth of one side of the preliminary lower electrode 214.

As illustrated in FIG. 3C, the first mask 220 may be removed.

For example, when the first mask 220 includes a photoresist, the first mask 220 may be removed by an ashing process and a strip process.

When the first mask 220 is removed, a second opening 224 may be formed on upper portions of the lower electrode 222, and the first and second insulating patterns 212 and 216.

Referring to FIG. 3D, a third insulating pattern 226 filling the second opening 224 may be formed.

The third insulating pattern 226 may include a nitride, such as silicon nitride. The third insulating pattern 226 may include a first portion extending in a downward direction and a second portion extending in a sideward direction.

A top surface of the third insulating pattern 226 may be even with top surfaces of the lower electrode 222 and the second insulating patterns 216.

The second and third insulating patterns 216 and 226 including a nitride may be formed so as to wrap an upper portion of the lower electrode 222. The second and third insulating patterns 216 and 226 including a nitride contain less moisture than an oxide, so as to minimize and/or prevent an electrical incorrect operation of a semiconductor device.

Referring to FIGS. 3E and 3F, a variable resistance pattern 228, an upper electrode 230, and a bit line 232 electrically connected to the lower electrode 222 may be formed.

More specifically, a variable resistance layer and an upper electrode layer may be sequentially formed. A second mask (not illustrated) may be formed on the upper electrode layer, and the upper electrode layer and the variable resistance layer may be etched using the second mask to form the variable resistance pattern 228 and the upper electrode 230. The variable resistance pattern 228 may have a line shape extending in a different direction from the extending direction of the word line 202. The variable resistance pattern 228 and the word line 202 may be perpendicular to each other.

The smaller an area where the variable resistance pattern 228 and the lower electrode 222 may be in contact with each other is, the less power may be used to drive a semiconductor device. The third insulating pattern 226 may be formed by etching a portion of the lower electrode 222. The variable resistance pattern 228 may be formed to contact a smaller area of the lower electrode 222 so that a semiconductor device may be driven using less power.

A bit line 232 electrically connected to the upper electrode 230 may be formed.

According to exemplary embodiments of the present general inventive concept, the bit line 232 may be electrically connected to the upper electrode 230 by a contact 234. According to exemplary embodiments of the present general inventive concept, the bit line 232 may be directly connected to the upper electrode 230.

A structure of a semiconductor device in accordance with the exemplary embodiments of the present general inventive concept is not limited to be manufactured by the manufacturing method illustrated in FIGS. 3A-3F and described above. A structure of a semiconductor device in accordance with the exemplary embodiments of the present general inventive concept may be realized by various manufacturing methods.

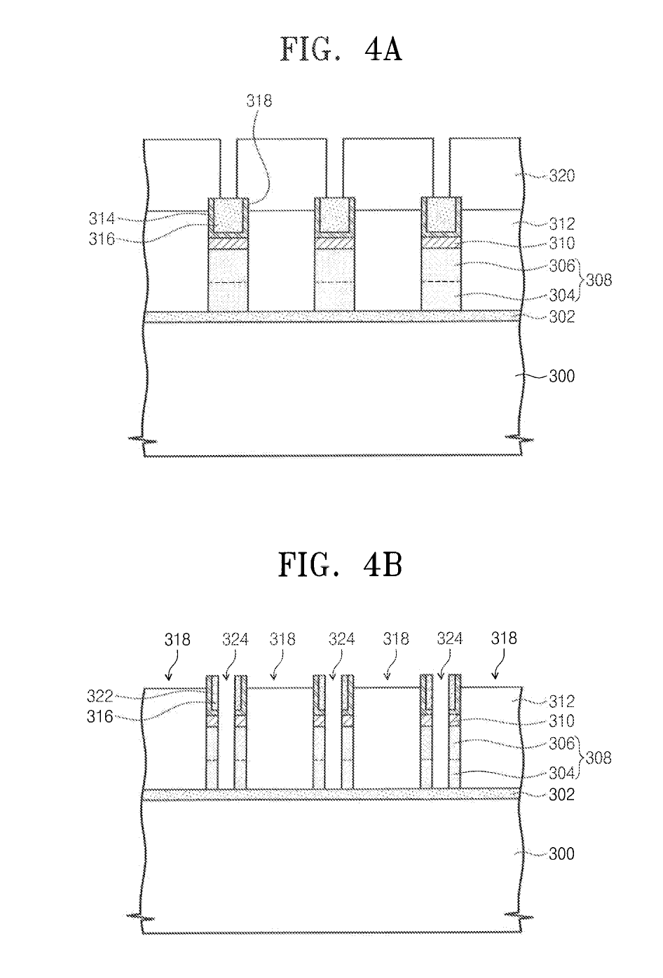

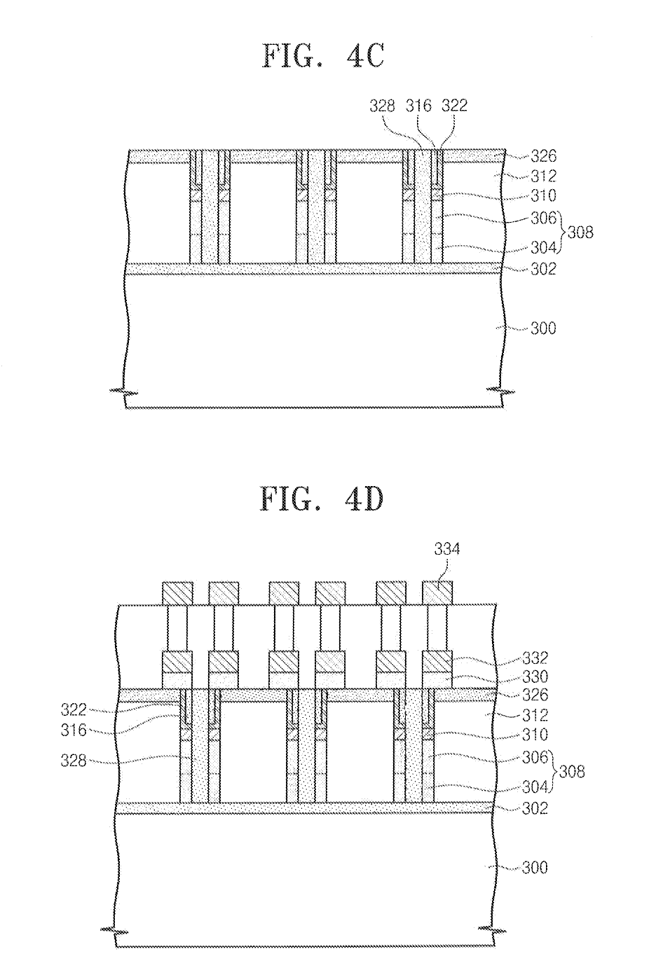

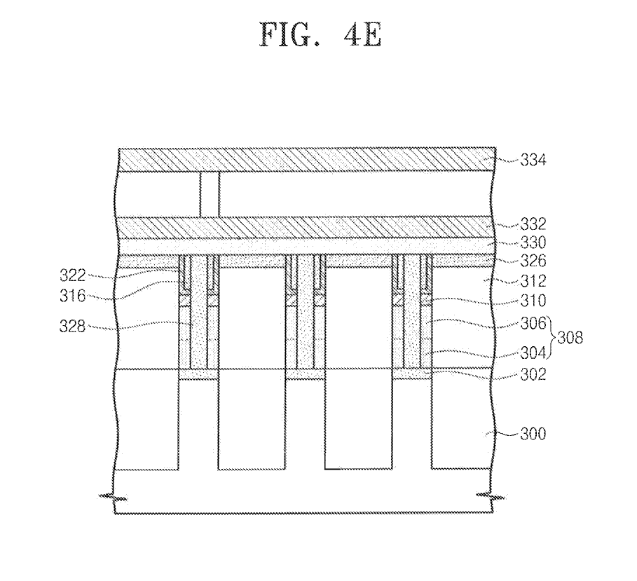

FIGS. 4A through 4E are cross-sectional views illustrating a method of manufacturing a semiconductor device in accordance with exemplary embodiments of the present general inventive concept. FIGS. 4A through 4D are cross-sectional views taken along the line X-X′ of a semiconductor device illustrated in FIG. 1B. FIG. 4E is a cross-sectional view taken along the line Y-Y′ of a semiconductor device illustrated in FIG. 1B.

Referring to 4A, a word line 302, a selection unit 308, an ohmic pattern 310, a preliminary lower electrode 314, first and second insulating patterns 312 and 316 and a first mask 320 may be formed on a substrate 300. The selection unit 308 may include a lower silicon layer 304 and an upper silicon layer 306. The lower silicon layer 304 may be doped with an impurity and the upper silicon layer 306 may be doped with another impurity. For example, the lower silicon layer 304 may be doped with a P-type impurity, and the upper silicon layer 306 may be doped with an N-type impurity. A first opening 318 may be formed on the first insulating pattern 312.

Since a process of forming the word line 302, the selection unit 308, the ohmic pattern 310, the preliminary lower electrode 314, and the first and second insulating patterns 312 and 316 is similar to the process illustrated in FIGS. 2A through 2I and described above, a detailed description will be omitted.

A first mask 320 may be formed on the lower electrode and the first and second insulating patterns 316 so as to partly expose the second insulating pattern 316.

Referring to FIG. 4B, the second insulating pattern 316, the preliminary lower electrode 314, the ohmic pattern 310 and the selection unit 308 may be etched using the first mask 320 as an etching mask.

From the etching, a plurality of lower electrodes 322, ohmic patterns 310 and selection units 308 may be formed.

The lower electrode 322 may be a bottom surface of a half ring shape and a structure extending from the bottom surface to an upper portion. A vertical cross section may have an L character structure or an inversed L character structure.

From the etching, structures including the lower electrode 322, the ohmic pattern 310 and the selection unit 308 may be formed, and a second opening 324 may be generated between the structures. The word line 302 may be exposed to a bottom surface of the second opening 324.

Referring to FIG. 4C, a third insulating pattern 326 and a fourth insulating pattern 328 to fill the first and second openings 318 and 324 respectively may be formed.

The third and fourth insulating patterns 326 and 328 may include silicon nitride. The top surfaces of the lower electrode 322 and the second through fourth insulating patterns 316, 326 and 328 may be even with one another.

Referring to FIGS. 4D and 4E, variable resistance patterns 330, upper electrodes 332 and bit lines 334 that are electrically connected to one another may be formed on the lower electrodes 322.

Since a process of forming the variable resistance patterns 330, the upper electrode 332 and bit lines 334 is similar to the process illustrated in FIGS. 3E and 3F and described above, a detailed description will be omitted.

A structure of a semiconductor device in accordance with exemplary embodiments of the present general inventive concept is not limited to be manufactured by the manufacturing method illustrated in FIGS. 4A-4E and described above. A structure of a semiconductor device in accordance with exemplary embodiments of the present general inventive concept may be realized by various manufacturing methods.

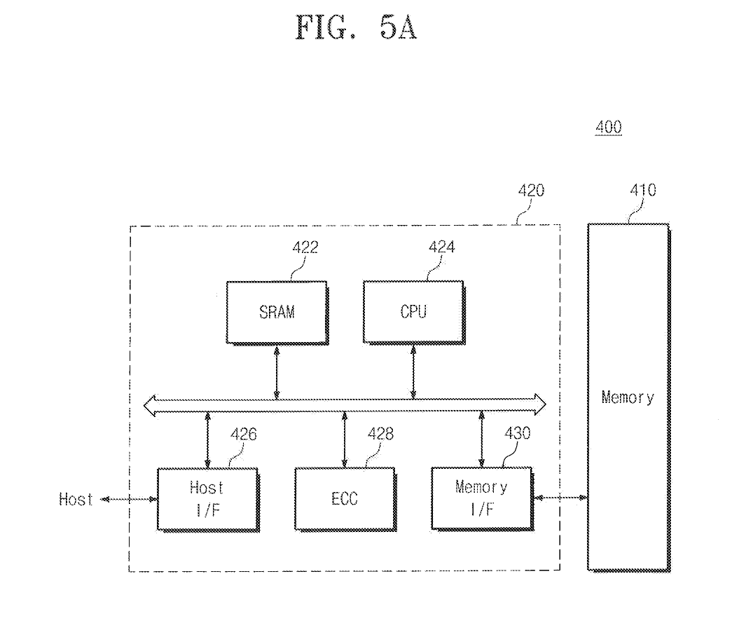

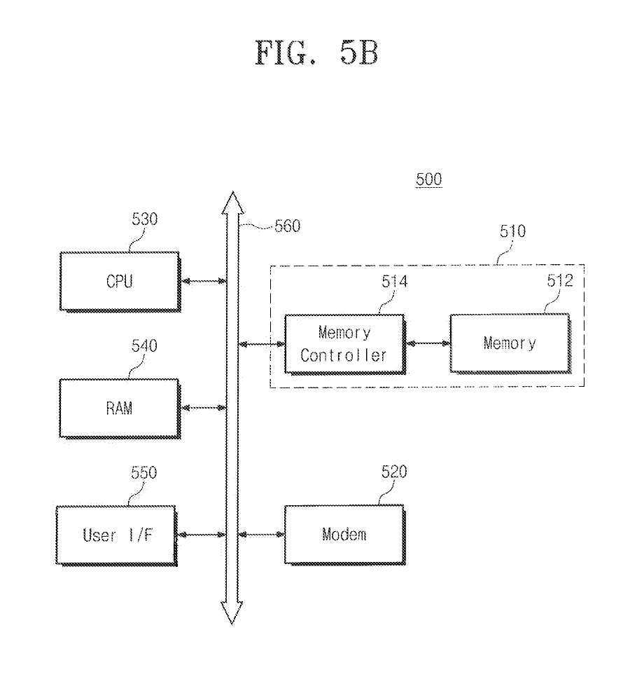

FIG. 5A is a block diagram illustrating a memory card including a variable resistance memory device in accordance with the exemplary embodiments of the present general inventive concept.

Referring to FIG. 5A, a pattern structure in accordance with exemplary embodiments of the present general inventive concept and a variable resistance memory device including the pattern structure may be applied to form a memory card 400. The memory card 400 may include a memory controller 420 to control a data exchange between a host and a resistance memory 410. A SRAM 422 (e.g., a static random access memory) may be used as an operation memory of a central processing unit (CPU) 424. A host interface 426 may include at least one data exchange protocol of the host connected to the memory card 400. An error correction code (ECC) 428 may detect and correct at least one error that may be included in data read from the resistance memory 410. A memory interface 430 can interface with the resistance memory 410. The central processing unit (CPU) 424 can control data exchange of the memory controller 420 with, for example, the memory 410.

The semiconductor memory 410 included with the memory card 400 may be formed according to the method of forming a variable resistance memory as described above in accordance with the exemplary embodiments of the present general inventive concept. Insulating patterns may be formed to be adjacent to an upper portion of the lower electrode include a nitride so as to suppress and/or minimize the generation of a void or a seam. The insulating patterns may not include moisture or may have a minimized amount of moisture, thereby preventing and/or minimizing an incorrect electrical operation of the variable resistance memory.

FIG. 5B is a block diagram illustrating an information processing system including a variable resistance memory device in accordance with exemplary embodiments of the present general inventive concept.

Referring to FIG. 5B, an information processing system 500 may include a semiconductor memory device in accordance with exemplary embodiments of the present general inventive concept, for example, a memory system 510 including a variable resistance memory. The information processing system 500 may include a mobile device or a computer. As an illustration, the information processing system 500 may include the memory system 510, a modem 520, a central processing unit (CPU) 530, a RAM 540 (e.g., a random access memory), and a user interface 550 that are electrically connected to a system bus 560. The memory system 510 may store data processed by the central processing unit (CPU) 530 and data inputted from the outside (e.g., via the user interface 550 and/or the modem 520). The memory system 510 may include a memory 512 and a memory controller 514. The memory system 510 may be the same as the memory card 500 described with reference to FIG. 5A. The information processing system 500 may be provided as a memory card, a solid state disk, a camera image sensor and an application chip set. For example, the memory system 510 may be a solid state disk (SSD). The information processing system 500 may stably and reliably store data in the memory system 510.

According to exemplary embodiments of the present general inventive concept, insulating patterns formed to be adjacent to an upper portion of the lower electrode include a nitride, thereby minimizing and/or preventing the insulating patterns from being etched when cleaning a top surface of the lower electrode. Generation of a void or a seam due to an etching of the insulating patterns may be suppressed, thereby improving an electrical operation of the semiconductor device.

Although several embodiments of the present general inventive concept have been illustrated and described, it will be appreciated by those skilled in the art that changes may be made in these embodiments without departing from the principles and spirit of the general inventive concept, the scope of which is defined in the appended claims and their equivalents. Therefore, the above-disclosed subject matter is to be considered illustrative, and not restrictive.

1. A semiconductor device, comprising:
a lower electrode having a hollow cylindrical shape of which an upper portion is open, the lower electrode being disposed on a substrate;
an insulator including a nitride to wrap the lower electrode;
a variable resistance pattern electrically connected to the lower electrode; and
an upper electrode electrically connected to the variable resistance pattern.

2. The semiconductor device of claim 1, wherein the insulator comprises:
a first insulating pattern to fill the hollow cylindrical shape of the lower electrode; and
a second insulating pattern formed to be adjacent to an outer sidewall of the upper portion of the lower electrode.

3. The semiconductor device of claim 1, wherein a vertical cross section of the lower electrode has a U character shape and a horizontal cross section of the lower electrode has a ring shape.

4. The semiconductor device of claim 3, wherein the variable resistance pattern is partly connected to the upper portion of the lower electrode.

5. The semiconductor device of claim 4, further comprising:
a third insulating pattern to insulate a space between the variable resistance patterns, the third insulating pattern being formed on the lower electrode and the insulator, where the third insulating pattern includes an oxide.

6. The semiconductor device of claim 2, wherein the insulator further comprises:
a fourth insulating pattern formed when removing one side of the lower electrode.

7. The semiconductor device of claim 6, wherein a vertical cross section of the lower electrode has a J character shape, an inversed J character shape, an L character shape or an inversed L character shape,

8. The semiconductor device of claim 2, wherein the insulator further comprises:
a fifth insulating pattern extending when penetrating the second insulating pattern and a bottom surface of the lower electrode.

9. The semiconductor device of claim 8, wherein a vertical cross section of the lower electrode has an L character shape or an inversed L character shape.

10. The semiconductor device of claim 1, further comprising:
a sixth insulating pattern wrapping an outer sidewall of a lower portion of the lower electrode, the sixth insulating pattern being formed on a lower portion of the first insulating pattern, wherein the sixth insulating pattern includes an oxide.

11. The semiconductor device of claim 1, further comprising:
a word line formed on the substrate;
a selection unit electrically connected to the word line and the lower electrode; and
a bit line electrically connected to the upper electrode.

12-20. (canceled)

21. A semiconductor device, comprising:
a lower electrode having a base and two sidewalls extending from the base that are different lengths, the lower electrode disposed on a substrate;
an insulator including a nitride, the insulator to fill the area between the two sidewalls of the lower electrode, to be disposed on at least one of the sidewalls, and to be disposed adjacent to outer portions of the two sidewalls;
a variable resistance pattern electrically connected to the lower electrode; and
an upper electrode electrically connected to the variable resistance pattern.

22. A semiconductor device, comprising:
a lower electrode having a base and two sidewalls extending from the base that are different lengths, the lower electrode disposed on a substrate;
an insulator including a nitride, the insulator having:
a first insulating pattern disposed adjacent to an outer side of each of the two sidewalls of the lower electrode;
a second insulting pattern to fill an area between the two sidewalls of the lower electrode;
a third insulating pattern formed on at least one of the two sidewalls of the lower electrode;
a variable resistance pattern electrically connected to the lower electrode; and
an upper electrode electrically connected to the variable resistance pattern.

23. (canceled)

24. A semiconductor device, comprising;
a lower electrode having a first base with a first sidewall extending therefrom, and a second base with a second sidewall extending therefrom, where the first base and the second base of the lower electrode are spaced apart from one another and are disposed on a substrate;
an insulator including a nitride, the insulator to fill the area between the first and second base and the first and second sidewalls, and to be disposed adjacent to outer portions of the first and second sidewalls;
a variable resistance pattern electrically connected to the lower electrode; and
an upper electrode electrically connected to the variable resistance pattern.

25. (canceled)

26. A memory system comprising:
a memory including:
a lower electrode having a hollow cylindrical shape of which an upper portion is open, the lower electrode being disposed on a substrate;
an insulator including a nitride to wrap the lower electrode;
a variable resistance pattern electrically connected to the lower electrode; and
an upper electrode electrically connected to the variable resistance pattern; and
a controller to control data read and write operations to the memory.
